(19) United States
(12) Patent Application Publication
(10) Pub. No.: US 2025/0214661 A1
(43) Pub. Date: Jul. 3, 2025

(54) HYBRID TRACTOR/TRAILER SYSTEM

(71) Applicant: STEWART & STEVENSON LLC, Houston, TX (US)

(72) Inventor: Jeff SMITH, Houston, TX (US)

(21) Appl. No.: 18/949,566

(22) Filed: Nov. 15, 2024

Related U.S. Application Data
(60) Provisional application No. 63/614,977, filed on Dec. 27, 2023.

(51) Int. Cl. B62D 59/04; B60K 1/00; B60K 17/04; B60L 7/10; B60L 15/20; B60L 50/60; B60L 58/12; B62D 53/08; G01L 5/00; G01R 31/382

(52) U.S. Cl. CPC B62D 59/04; B60K 1/00; B60K 17/043; B60L 7/10; B60L 15/20; B60L 50/60; B60L 58/12; B60L 2200/28; B60L 2240/421; B62D 53/0842; G01L 5/00; G01R 31/382

(57) ABSTRACT

The hybrid tractor/trailer system includes a tractor and a trailer connected to the tractor at a trailer connection. The hybrid tractor/trailer system also includes a battery system, the battery system mechanically connected to the trailer. The hybrid tractor/trailer system further includes a motor controller, wherein the motor controller is in electrical communication with the battery system and an electric motor, the motor in electrical communication with the motor controller. In addition, the hybrid tractor/trailer system includes a gearbox, the gearbox in mechanical communication with the motor and an axle, the axle in mechanical communication with the motor.

### CROSS-REFERENCE TO RELATED APPLICATIONS

This application is a nonprovisional application which claims priority from U.S. provisional application No. 63/614,977, filed Dec. 27, 2023, which is incorporated by reference herein in its entirety.

### TECHNICAL FIELD/FIELD OF THE DISCLOSURE

The present disclosure relates generally to transportation and use of electric axles on trailers in combination with a tractor.

### BACKGROUND OF THE DISCLOSURE

Traditionally, tractor-trailer combinations' pull and load capacity are limited based upon the limits of the drive train, and the axle and suspension systems of the tractor and trailer. In certain circumstances, it may be difficult with traditional tractor-trailer combinations to pull heavy loads or loads over rough terrain.

### SUMMARY

A hybrid tractor/trailer system is disclosed. The hybrid tractor/trailer system includes a tractor and a trailer connected to the tractor at a trailer connection. The hybrid tractor/trailer system also includes a battery system, the battery system mechanically connected to the trailer. The hybrid tractor/trailer system further includes a motor controller, wherein the motor controller is in electrical communication with the battery system and an electric motor, the motor in electrical communication with the motor controller. In addition, the hybrid tractor/trailer system includes a gearbox, the gearbox in mechanical communication with the motor and an axle, the axle in mechanical communication with the motor.

### BRIEF DESCRIPTION OF THE DRAWINGS

The present disclosure is best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is perspective view of a trailer with one or more electrically powered axles consistent with certain embodiments of the present disclosure.

FIG. 2 is an underside view of a trailer consistent with certain embodiments of the present disclosure.

FIG. 3 is a side view of a tractor/trailer combination consistent with certain embodiments of the present disclosure.

FIG. 4 is a block diagram of a sensor system consistent with certain embodiments of the present disclosure.

FIG. 5 is a schematic drawing of a tractor/trailer combination consistent with certain embodiments of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

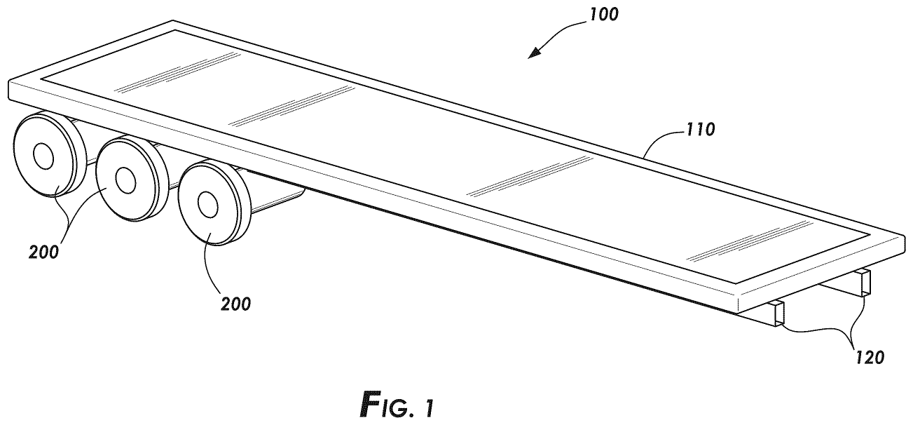

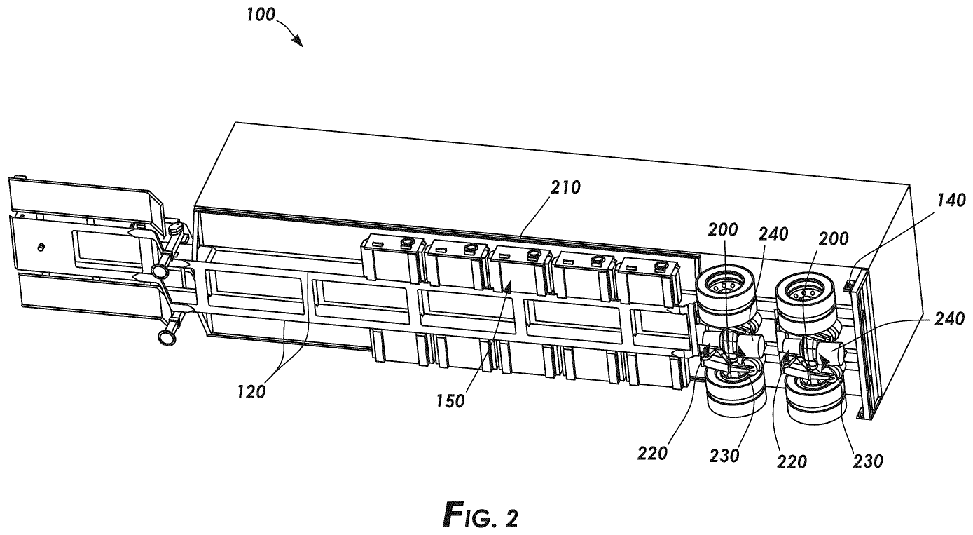

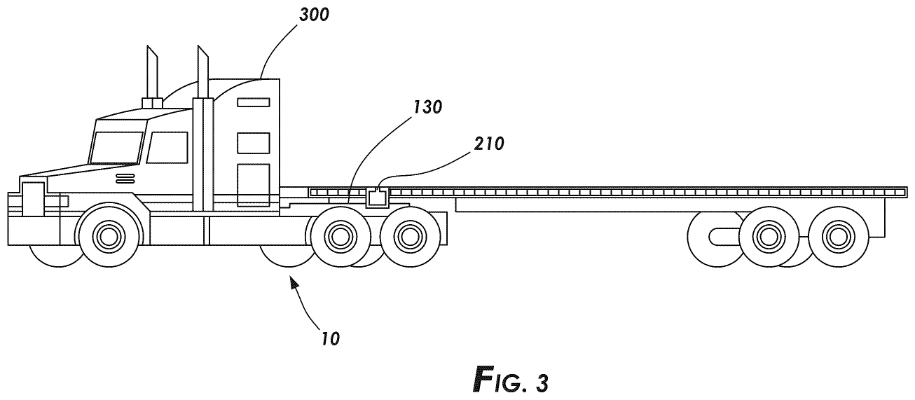

FIGS. 1 and 2 depict trailer 100 with electrically powered axles 200 consistent with certain embodiments of the present disclosure. Trailer 100 may include trailer deck 110 and frame rails 120 positioned below trailer deck 110 as well as tractor connection 130 (shown in FIG. 3), which may be, for example, a kingpin or gooseneck connection. FIG. 3 shows trailer 100 in combination with tractor 300 in hybrid tractor/trailer system 10.

Electrically powered axles 200 may increase pull and load capacity of trailer 100, thereby increasing the load capacity that the combined tractor 300 and trailer 100 can transport. Electrically powered axles 200 may be in electrical communication with battery system 210. Battery system 210 may include a plurality of battery modules 150 and may be installed on trailer 100, such as between frame rails 120 or outside frame rails 120, as shown in FIG. 2, at tractor connection 130 of trailer 100, as shown in FIG. 3, or at trailer rear 140. As one of ordinary skill in the art will appreciate with the benefit of this disclosure, positioning of battery module 150 is not critical and battery modules 150 may be positioned as needed. Battery system 210 supplies the power to operate electrically powered axles 200.

With further attention to FIG. 2, battery system 210 may be in electrical connection with electric motor 220. FIG. 2 depicts an electric motor 220 for each electrically powered axle 200. Electric motor 220 is in mechanical connection with electrically powered axle 200 through reduction gearbox 230. Also shown in FIG. 2 is motor controller 240 in electrical connection with electric motor 220. Motor controller 240 is adapted to vary the speed of electric motor 220, thereby controlling the speed of electrically powered axle 200. In certain embodiments, motor controller 240 may also be adapted to regeneratively brake for charging of battery modules 150.

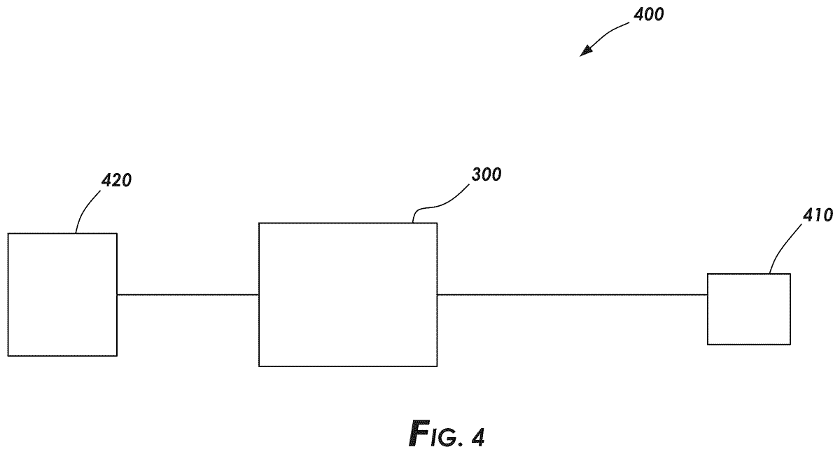

In certain embodiments, as schematically shown in FIG. 4, sensor system 400 includes state of charge sensor 410 to measure data on the battery system 210 state of charge and communicate that information electrically to tractor 300. Sensor system 400 may also include strain gauge sensor 420, for example, installed at tractor connection 130. Strain gauge sensor 420 may electronically communicate to tractor 300 the load placed on trailer 100 to the operator.

As discussed above, in certain embodiments, the combination of electrically powered axles 200 and motor controller 240 may be regenerative, in that electrically powered axles 200 may transfer kinetic energy back to battery system 210 when battery system 210 is not discharging. Specifically kinetic energy may be transferred from electrically powered axles 200 and battery system 210 during deceleration and braking.

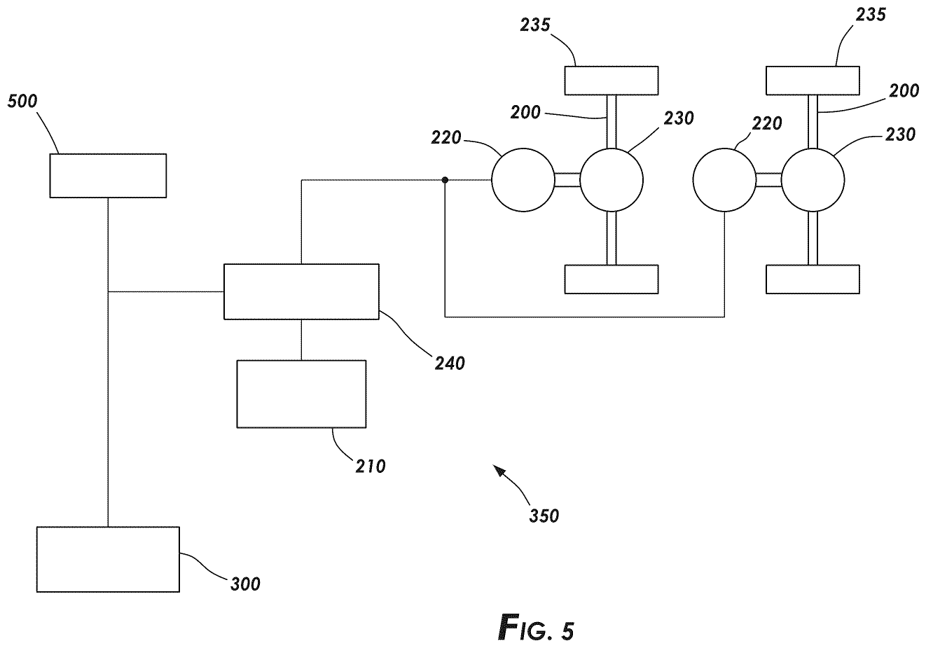

FIG. 5 is a schematic drawing of tractor/trailer combination 350. Tractor 300 is connected to trailer load 500. Motor controller 240, having regenerative braking, is electrically connected to battery system 210 and to electric motors 220. As described above, electric motors 220 may be mechanically connected to reduction gearboxes 230. Reduction gearboxes 230 may be mechanically attached to electrically powered axles 200, which are in turn connected to tires 235.

Thus, in certain embodiments, electrically powered axles 200 and pulling from tractor 300 may provide more push/pull power to trailer 100 than tractor 300 alone.

The foregoing outlines features of several embodiments so that a person of ordinary skill in the art may better understand the aspects of the present disclosure. Such features may be replaced by any one of numerous equivalent alternatives, only some of which are disclosed herein. One of ordinary skill in the art should appreciate that they may readily use the present disclosure as a basis for designing or modifying other processes and structures for carrying out the same purposes and/or achieving the same advantages of the embodiments introduced herein. One of ordinary skill in the art should also realize that such equivalent constructions do not depart from the spirit and scope of the present disclosure and that they may make various changes, substitutions, and alterations herein without departing from the spirit and scope of the present disclosure.

1. A hybrid tractor/trailer system comprising:
a tractor;
a trailer connected to the tractor at a trailer connection;
a battery system, the battery system mechanically connected to the trailer;
a motor controller, wherein the motor controller is in electrical communication with the battery system;
an electric motor, the motor in electrical communication with the motor controller;
a gearbox, the gearbox in mechanical communication with the motor; and
an axle, the axle in mechanical communication with the motor.

2. The hybrid tractor/trailer system of claim 1 further comprising a sensor system, the sensor system including:
a state of charge sensor, the state of charge sensor electrically connected to the battery system and the tractor; and
strain gauge sensor, the strain gauge sensor mechanically connected at the trailer connection and electrically connected to the tractor.

3. The hybrid tractor/trailer system of claim 1, wherein the trailer includes a trailer deck and frame rails positioned below the trailer deck.

4. The hybrid tractor/trailer system of claim 3, wherein the trailer connection is a kingpin or gooseneck connection.

5. The hybrid tractor/trailer system of claim 4, wherein the battery system includes a plurality of battery modules.

6. The hybrid tractor/trailer system of claim 5, wherein the plurality of battery modules is installed between the frame rails or outside the frame rails on an underside of the trailer.

7. The hybrid tractor/trailer system of claim 6, wherein the plurality of batteries is installed at the trailer connection or a trailer rear.

8. The hybrid tractor/trailer system of claim 5, wherein the electrically powered axles are adapted to provide kinetic energy to the batteries during deceleration and braking.

9. The hybrid tractor/trailer system of claim 1, wherein the motor controller is adapted to vary the speed of the electric motor.

10. The hybrid tractor/trailer system of claim 1, wherein the gearbox is a reduction gearbox.

11. The hybrid tractor/trailer system of claim 1, wherein the electric axles are mechanically connected to tires.
